(19) United States
(12) Patent Application Publication
(10) Pub. No.: US 2025/0062253 A1
(43) Pub. Date: Feb. 20, 2025

(54) RF SWITCH DEVICE AND MANUFACTURING METHOD THEREOF

(71) Applicant: DB HiTek Co., Ltd., Bucheon-si (KR)

(72) Inventor: Ja Geon KOO, Eumseong-gun (KR)

(21) Appl. No.: 18/489,927

(22) Filed: Oct. 19, 2023

(30) Foreign Application Priority Data
Aug. 18, 2023 (KR) 10-2023-0108116

(51) Int. Cl. H01L 23/66; H01L 29/06; H01L 29/66; H01L 29/78

(52) U.S. Cl. CPC H01L 23/66; H01L 29/0607; H01L 29/0649; H01L 29/66484; H01L 29/7831; H01L 2223/6688

(57) ABSTRACT

Provided is an RF switch device and a manufacturing method thereof and, more particularly, an RF switch device and a manufacturing method thereof that improve breakdown voltage characteristics and prevent an increase in the figure of merit (FoM) value, which has a trade-off relationship with the breakdown voltage characteristics, by decreasing the path along which holes move in a body region to a body contact by including a first (gate) electrode extending along a first direction between opposite ends of a second (gate) electrode extending in a second (orthogonal) direction.

### CROSS REFERENCE TO RELATED APPLICATION

The present application claims priority to Korean Patent Application No. 10-2023-0108116, filed Aug. 18, 2023, the entire contents of which are incorporated herein for all purposes by this reference.

### BACKGROUND OF THE INVENTION

### Field of the Invention

The present disclosure relates to an RF switch device and a manufacturing method thereof and, more particularly, to an RF switch device and a manufacturing method thereof, which improve breakdown voltage characteristics and prevent the figure of merit (FoM) value, which has a trade-off relationship with the breakdown voltage characteristics, from increasing by decreasing the path along which holes move in a body region of the device to a body contact of the device by including a first electrode in the device that extends along a first direction (e.g., the length of a gate electrode in the device) between opposite ends of a second electrode in the device (e.g., along a second direction different from the first direction).

### Description of the Related Art

In general, when an RF switch device is manufactured from silicon, there are many constraints on device characteristics, and the characteristics may deteriorate. A metal oxide semiconductor (MOS) transistor includes a gate electrode and a source and drain in a substrate on opposite sides of the gate electrode, and is one of the representative devices that make up an integrated circuit. It is widely used as a switch for control, logic, and power across memory and non-memory devices.

The performance of RF switch devices can be examined in terms of figure of merit (FoM) and breakdown voltage. A way to increase the breakdown voltage is to increase the gate length, but as the length of the gate becomes longer, the on-resistance (Ron) increases, resulting in an increase in the FoM value. Conversely, if the gate length is reduced, the FoM value decreases while the breakdown voltage decreases. That is, since the FoM value and the breakdown voltage are in a trade-off relationship, there are limits to improving both FoM characteristics and breakdown voltage characteristics simultaneously.

Moreover, in a typical RF switch device, during operation, when a sufficiently high voltage is applied to the drain, holes generated in the drain by impact ionization escape through the substrate in a bulk MOSFET, whereas in the case of a silicon-on-insulator (SOI) MOSFET, holes cannot escape through the substrate since the body region is floating. Such holes need to escape through the source. However, holes that are unable to escape in the SOI MOSFET accumulate in the floating body region near the source. As a result, the electric potential in the floating body region increases, and this increase in potential reduces the threshold voltage so that a kink phenomenon occurs, in which an electric current suddenly jumps before the breakdown voltage is reached.

FIG. 1 is a plan view of a conventional RF switch device.

Referring to FIG. 1, in a typical conventional RF switch device 9, a body contact 940 is connected to a body region (not shown) having a first conductivity type in order to solve problems caused by a floating body region. To be specific, a source 920 is on one side of the gate 910, and a drain 930 is on an opposite side of the gate 910. In addition, a body contact 940 having a high concentration of first conductivity type dopant ions is on another side of the gate 910. Thus, during device operation, holes in the body region are released through the body contact 940 (e.g., by flowing through a P+ channel therein).

The gate 910 may include a first structure 911 extending along a first direction, and one or more second structures 913 connected to the first structure 911 and extending along a second direction. Due to this layout, the gate 910 will have a T-type shape. The body region may also have a T-type shape below the gate 910. One body contact 940 may be on one side of the first structure 911, opposite from the side including the second structures 913.

In this structure, since holes in the body region should be released through the body contact 940, the holes need to escape by moving in one direction. Thus, there may be constraints on the smooth release of the holes. In addition, for the holes in the body region below ends of the second structures 913 distal from the first structure 911, as the distance from the body contact 940 increases, the escape path also lengthens, and thus there may be additional constraints on the smooth release of the holes. As a result, the breakdown voltage characteristics of the device 9 deteriorate, which can be problematic.

To solve the above problems, an RF switch device with an improved structure and a manufacturing method thereof are disclosed, which will be described in detail later.

### DOCUMENT OF RELATED ART

Korean Patent Application Publication No. 10-2022-0136280, entitled “TRANSISTORS HAVING SELF-ALIGNED BODY TIE.”

### SUMMARY OF THE INVENTION

The present disclosure has been made to solve the problems of the related art, and an objective of the present disclosure is to provide an RF switch device and a manufacturing method thereof, which allow holes in a body region to be released relatively smoothly and/or easily, thereby improving breakdown voltage characteristics by including a body contact connected to or in contact with the body region in order to prevent holes (e.g., generated by impact ionization) from accumulating in the floating body region and causing a kink phenomenon due to an increase in the electric potential of the body region.

In addition, an objective of the present disclosure is to provide an RF switch device and a manufacturing method thereof, which prevent device characteristics from deteriorating by decreasing the length of the path along which holes in the body region move to the body contact by including a first electrode extending along a first direction of a gate electrode between opposite ends of a second electrode in a second direction that may be orthogonal to the first direction.

Furthermore, an objective of the present disclosure is to provide an RF switch device and a manufacturing method thereof, which improve breakdown voltage characteristics and prevent an increase in the figure of merit (FoM) value, which has a trade-off relationship with the breakdown voltage characteristics, by including or utilizing a pair of body contacts, so that holes may escape in more than one direction.

The present disclosure may be implemented by one or more embodiments having the following configurations to achieve the above-described objectives.

According to one or more embodiments of the present disclosure, there is provided an RF switch device, including a buried oxide (BOX) layer (e.g., in a semiconductor substrate, such as a single crystal silicon wafer or a silicon-on-insulator [SOI] wafer); a semiconductor layer on or over the BOX layer, and a gate electrode on or over the semiconductor layer, wherein the gate electrode may include a first electrode extending along a first direction; and at least one second electrode extending along a second direction, wherein the first electrode may be between opposite ends of the second electrode. Alternatively, the gate electrode may comprise first and second pluralities of second electrodes on opposite sides of the first electrode. The first electrode may be a main or primary branch of the gate electrode, and the first and second pluralities of second electrodes may be secondary branches of the gate electrode orthogonal to the first electrode, and integral with and/or extending from the first electrode.

According to one or more other embodiments of the present disclosure, in the RF switch device, the first electrode may be substantially in a center between the opposite ends of the second electrode in the second direction.

According to one or more still other embodiments of the present disclosure, the RF switch device may further include a source and a drain adjacent to the second electrode and in the semiconductor layer, and a body region in the semiconductor layer, extending along or below the gate electrode.

According to one or more still other embodiments of the present disclosure, in the RF switch device, the body region may extend uninterruptedly along the first direction below the first electrode.

According to one or more still other embodiments of the present disclosure, the RF switch device may further include a device isolation film in the semiconductor layer, surrounding the source and the drain.

According to one or more still another embodiments of the present disclosure, the RF switch device may further include a body contact in the semiconductor layer, at an end of the first electrode.

According to one or more still other embodiments of the present disclosure, in the RF switch device, the body contact may be or comprise an impurity doped region having a first conductivity type, and may have a higher concentration of impurities and/or dopant compared to the body region.

According to one or more still other embodiments of the present disclosure, in the RF switch device, the device isolation film may include a first isolation film in the semiconductor layer, surrounding the source, the drain, and the body contact; and a second isolation film extending along the second direction between the body contact and the source and drain adjacent to the body contact.

According to one or more still other embodiments of the present disclosure, in the RF switch device, the second isolation film may terminate under an end of the first electrode, and the body region may extend uninterruptedly in the semiconductor layer below the first electrode.

According to one or more still other embodiments of the present disclosure, in the RF switch device, the body region may have an end connected to or in contact with the body contact.

According to one or more still other embodiments of the present disclosure, there is provided an RF switch device, including a buried oxide (BOX) insulating layer; a semiconductor layer on or over the BOX layer; a gate electrode on or over the semiconductor layer, a body region comprising a first conductivity type impurity doped region below the gate electrode; and a pair of first conductivity type body contacts spaced apart along a first direction, wherein the gate electrode may include a first electrode extending along the first direction; and at least one second electrode extending along a second direction, wherein the first electrode may cross or intersect the at least one second electrode and may have opposite ends in the first direction that extend to the pair of body contacts or that overlap or are adjacent to the body contacts.

According to one or more still other embodiments of the present disclosure, in the RF switch device, the body region may have opposite ends connected to or in contact with the pair of body contacts.

According to one or more still other embodiments of the present disclosure, the RF switch device may further include a source and a drain in the semiconductor layer, respectively on opposite sides of the body region on a side (e.g., of the gate electrode) of the second electrode.

According to one or more still other embodiments of the present disclosure, in the RF switch device, the body region may extend along the first direction below the first electrode, and may extend along the second direction below the second electrode.

According to one or more still other embodiments of the present disclosure, in the RF switch device, the body region may extend along the first direction from approximately a center of the device along the second direction and may be connected to or in contact with the pair of body contacts.

According to one or more embodiments of the present disclosure, there is provided a method of manufacturing an RF switch device, including forming a body contact extending along a second direction in a semiconductor layer on a BOX layer; forming a device isolation film in the semiconductor layer; forming an impurity doped region in the semiconductor layer, forming a gate electrode on or over the semiconductor layer; and completing a body region by forming a source and a drain in the semiconductor layer, wherein the gate electrode may include a first electrode extending along a first direction and at least one second electrode extending along the second direction, and the first electrode may be between opposite ends of the second electrode.

According to one or more other embodiments of the present disclosure, in the manufacturing method of an RF switch device, the body region may extend along substantially the same path as the gate electrode.

According to one or more other embodiments of the present disclosure, in the manufacturing method of an RF switch device, the body region may be connected to or in contact with the body contact.

According to one or more other embodiments of the present disclosure, in the manufacturing method of an RF switch device, the body contact may comprise a pair of body contacts spaced apart along the first direction.

According to one or more other embodiments of the present disclosure, in the manufacturing method of an RF switch device, the device isolation film may extend along the second direction from the body contact or a location adjacent thereto, but may terminate below the first electrode.

The present disclosure may have one or more of the following effects resulting from the above configurations.

According to the present disclosure, it is possible to improve breakdown voltage characteristics since holes in the body region are released relatively smoothly and/or easily by including a body contact connected to the body region in order to prevent the holes (e.g., generated by impact ionization) from accumulating in the floating body region and causing a kink phenomenon due to an increase in the electric potential of the body region.

In addition, according to the present disclosure, it is possible to prevent device characteristics from deteriorating by decreasing the path along which holes move in the body region to the body contact by including a first electrode (e.g., a first gate electrode) extending along a first direction between opposite ends of a second electrode in a second direction.

Furthermore, according to the present disclosure, it is possible to improve breakdown voltage characteristics and prevent an increase in the figure of merit (FoM) value, which has a trade-off relationship with the breakdown voltage characteristics, by utilizing or including a pair of body contacts so that holes are released in more than one direction.

Meanwhile, it should be added that even if certain effects are not explicitly mentioned herein, the effects described in the following specification expected by the technical features of the present disclosure and their potential effects are treated as if they are explicitly described in the present specification.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view of a conventional RF switch device;

FIG. 2 is a plan view of an RF switch device according to one or more embodiments of the present disclosure;

FIG. 3 is a cross-sectional view taken along line A-A′ of the RF switch device shown in FIG. 2;

FIG. 4 is a cross-sectional view taken along line B-B′ of the RF switch device shown in FIG. 2; and

FIGS. 5 to 9 are views showing structures formed in an exemplary manufacturing method of an RF switch device according to one or more embodiments of the present disclosure.

### DETAILED DESCRIPTION OF THE INVENTION

The embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those of ordinary skill in the art.

Hereinafter, it should be noted that when one component is described as being “on”, “above”, an “upper side of”, or an “upper part of” another component, the one component may be directly on the other component, or the one component may be a certain distance from the other component. When the one component is at a certain distance from another component, one or more third components may be between the one component and the other component. In addition, when one component is expressed as being “directly on another component” or “directly above another component”, no other component is between the one component and the other component.

In addition, it should be noted that, although terms such as first, second, etc. may be used to describe various items such as various elements, areas, and/or parts, the items are not limited by these terms, and a second configuration does not presuppose a first configuration.

The term “metal oxide semiconductor” (MOS) is a general term, and “M” is not limited to only metal and may be any of various types of conductors. Also, “S” may be a substrate or a semiconductor structure, and “O” is not limited to oxide and may include various types of organic or inorganic insulating materials.

Furthermore, the conductivity type of a doped region or component may be defined as “p-type” or “n-type” according to the main carrier characteristics, but this is only for convenience of description, and the technical spirit of the present disclosure is not limited to what is illustrated. For example, hereinafter, “p-type” or “n-type” may be replaced with the more general terms “first conductivity type” or “second conductivity type”, and here, the first conductivity type may refer to p-type, and the second conductivity type may refer to n-type.

Furthermore, it should be understood that “high concentration” and “low concentration” referring to the doping concentration of an impurity region refers to the relative doping concentration of the impurity region to other impurity regions.

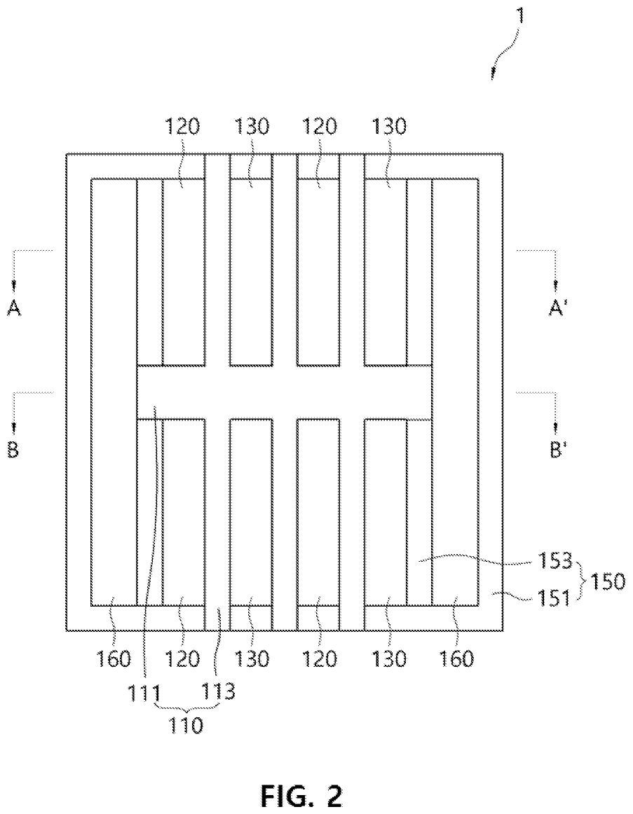

The term “first direction” used below may be understood to mean the x-axis direction on the plan view according to FIG. 2, and the term “second direction” may mean the y-axis direction or a direction perpendicular to the first direction.

In addition, in the following, one or more contacts or plugs may be on a source, a drain, a gate electrode, and/or a second well, but for convenience of explanation, detailed descriptions thereof will be omitted.

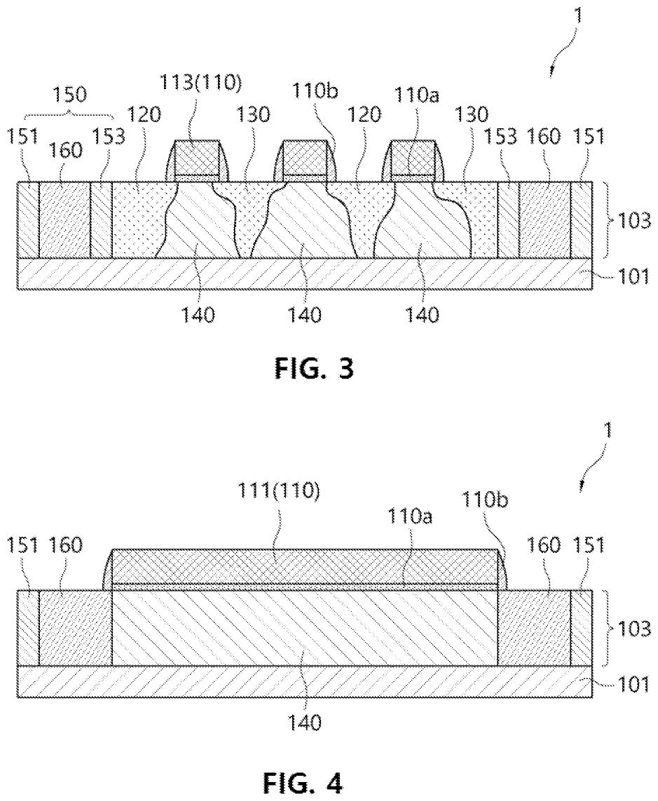

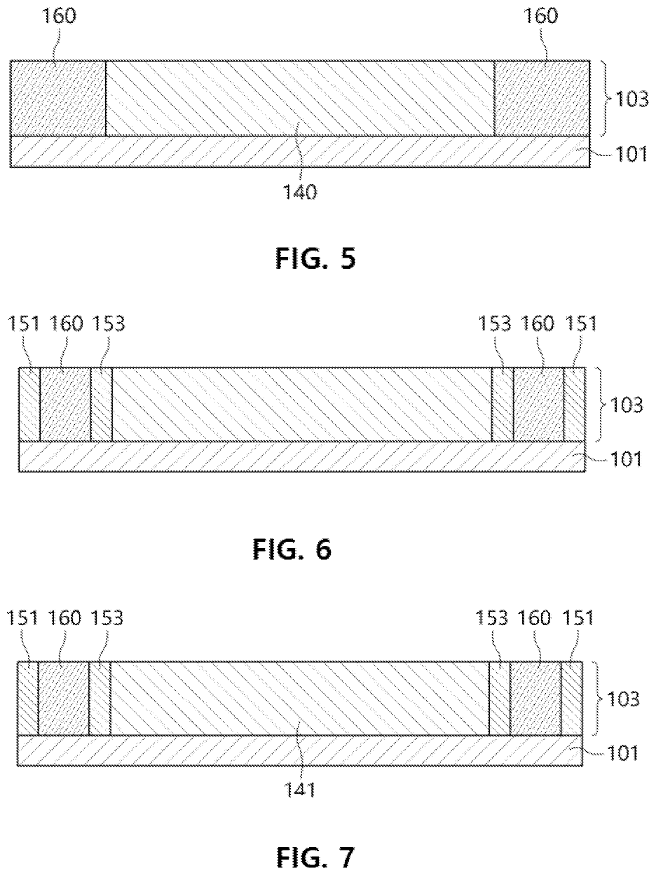

FIG. 2 is a plan view of an RF switch device according to one or more embodiments of the present disclosure; FIG. 3 is a cross-sectional view taken along line A-A′ of the RF switch device shown in FIG. 2; and FIG. 4 is a cross-sectional view taken along line B-B′ of the RF switch device shown in FIG. 2.

Hereinafter, the RF switch device 1 according to one or more embodiments of the present disclosure will be described in detail with reference to the accompanying drawings.

Referring to FIGS. 2 to 4, the present disclosure relates to an RF switch device and, more particularly, to an RF switch device 1 which improves breakdown voltage characteristics and prevents an increase in the figure of merit (FoM) value, which has a trade-off relationship with the breakdown voltage characteristics, by decreasing the path along which holes move in a body region to a body contact by including a gate electrode 110 having a first electrode (e.g., a first gate electrode portion) 111 having a longest dimension extending along a first direction between opposite ends of a second electrode (e.g., a second gate electrode portion) 113 having a longest dimension extending along in a second direction orthogonal to the first direction.

The structure of the RF switch device 1 according to embodiment(s) of the present disclosure will be described. A buried oxide (BOX) layer 101, which may function as an insulating layer, may be in or on a substrate such as a monolithic silicon wafer or a silicon-on-insulator (SOI) wafer, and a semiconductor layer 103 may be on or over the BOX layer 101. The semiconductor layer 103 is electrically isolated by device isolation films 150 and 151 so that individual devices on and/or in the semiconductor layer 103 may be driven separately. In addition, the device isolation film 150 may comprise, for example, an STI (shallow trench isolation) film, and may have substantially the same thickness as the semiconductor layer 103, but there is no particular limitation thereto.

In addition, the gate electrode 110 may be on or over the semiconductor layer 103. The gate electrode 110 may include the first electrode 111 extending along the first direction and one or more second electrodes 113 extending along the second direction. One end of each second electrode 113 is connected to, in contact with, and/or integral with the first electrode 111, and the gate electrode 110 may comprise a plurality of second electrodes 113 in the active region of the device 1 a predetermined distance apart from each other along the first direction. In the drawing, three second electrodes 113 are spaced apart from each other, but it should be noted that there is no specific limit to the number of second electrodes 113.

Referring to FIG. 2, the first electrode 111 preferably extends along the first direction at an arbitrary position between opposite ends of the second electrodes 113 in the second direction, and it is more preferable that the first electrode 111 extends along the first direction from approximately the center between opposite ends of the second electrodes 113 extending along the second direction. Thus, the gate electrode 110 may have an H-type shape. Opposite ends of the first electrode 111 may extend to a pair of body contacts 160 or to locations that overlap or are adjacent to the body contacts 160.

The gate electrode 110 including the first electrode 111 and the second electrode(s) 113 may include, for example, a conductive polysilicon, a metal, a conductive metal nitride, or a combination thereof, and may be formed by chemical vapor deposition (CVD), physical vapor deposition (PVD), atomic layer deposition (ALD), metalorganic atomic layer deposition (MOALD), or metalorganic chemical vapor deposition (MOCVD), etc. A gate insulating film 110a may be between the gate electrode 110 and the semiconductor layer 103. The gate insulating film 110a may include a silicon oxide film (e.g., silicon dioxide), a high-k dielectric film, or a combination thereof. The gate insulating film 110a may be formed by ALD, CVD, PVD and/or thermal oxidation.

A gate spacer 110b may be on sidewalls of the gate electrode 110, and the gate spacer 110b may include an oxide film (e.g., silicon dioxide), a nitride film (e.g., silicon nitride), or a combination thereof.

In addition, referring to FIGS. 2 and 4, in the active region, one or more sources 120 and one or more drains 130 may be in the semiconductor layer 103 on opposite sides of the second electrode 113. The source(s) 120 and the drain(s) 130 may be or comprise high-concentration impurity doped regions having a second conductivity type. The source(s) 120 and the drain(s) 130 may alternate and be spaced apart along the first direction. For example, the source(s) 120 and the drain(s) 130 may be respectively on the left side and on the right side of particular second electrode 113. In addition, referring to FIGS. 2 to 4, the source(s) 120 and the drain(s) 130 may not be in a lower portion of the semiconductor layer 103 or substantially below the first gate electrode 111, but may be in the semiconductor layer 103 on opposite sides of the second electrode(s) 113. As shown in FIG. 2, for example, when three second electrodes 113 are in the active region and are spaced apart from each other, four sources 120 and four drains 130 may be present.

Referring to FIGS. 3 and 4, a body region 140 may be in the semiconductor layer 103. The body region 140 is an impurity doped region having a first conductivity type, and is preferably doped with a lower concentration of impurities compared to the body contacts 160, which will be described later. In addition, the body region 140 may be below the gate electrode 110. The body region 140 may extend substantially along the same path as the gate electrode 110.

Therefore, the body region 140 may be in the semiconductor layer 103 between a source 120 and an adjacent drain 130, and may extend along the second direction below the second gate electrode(s) 113. In addition, the body region 140 may extend in the semiconductor layer 103 uninterruptedly along the first direction immediately below the first gate electrode 111, and be connected to or in contact with the body contact 160.

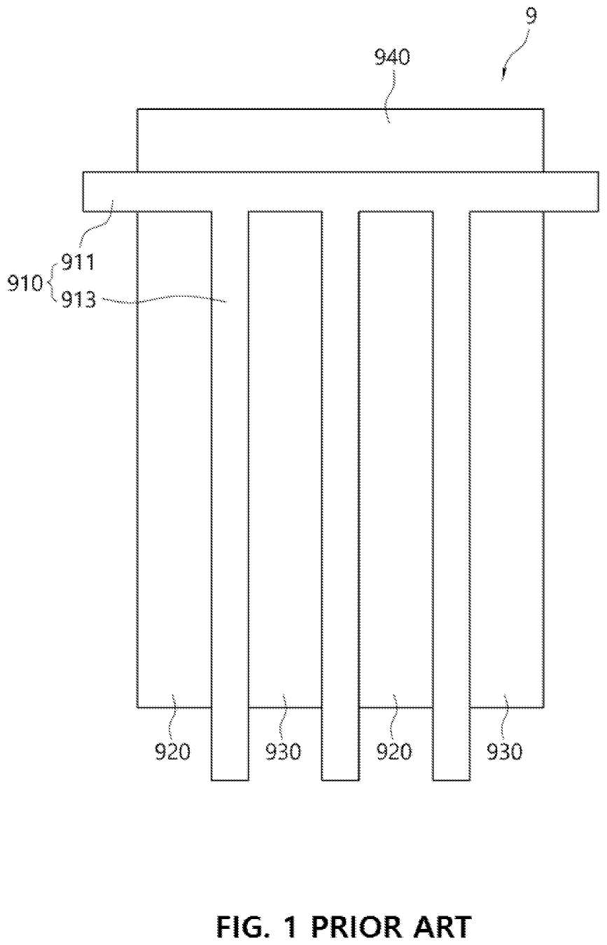

Hereinafter, the structure and problems of the conventional RF switch device 9 (FIG. 1) will be described in detail, as well as the RF switch device 1 according to one or more embodiments of the present disclosure to solve these problems.

In SOI MOSFETs, the body region is electrically isolated from the substrate (or a bottom thereof) and thus floats electrically. When a sufficiently high voltage is applied to the drain and the SOI MOSFET operates, the channel electrons may induce impact ionization near the drain. Since the body region is floating, holes generated by impact ionization cannot escape to the substrate and accumulate in the body region. Accordingly, the threshold voltage of the SOI MOSFET decreases due to the increase in the electric potential of the floating body, and eventually the kink phenomenon occurs. In order to prevent such problems, referring to FIG. 1, generally, a body contact 940 is included so that the holes in the body region escape or are released through the body contact.

Referring to FIG. 1, in the typical conventional RF switch device 9, a body contact 940 is connected to a body region (not shown) having the first conductivity type in order to solve problems caused by the floating body region. To be specific, the typical conventional RF switch device 9 includes a gate 910, a source 920 on one side of the gate 910, and a drain 930 are on another side of the gate 910. In addition, a body contact 940 having a high concentration of first conductivity type is on another side of the gate 910. Thus, during device operation, holes in the body region are released by flowing through the body contact 940 (e.g., a P+ channel therein).

The gate 910 may include a first structure 911 extending along a first direction, and one or more second structures 913 connected to the first structure 911 and extending along a second direction. Due to this layout, the gate 910 may have a T-type shape. The body region may also have a T-type shape below the gate 910. One body contact 940 may be on one side of the first structure 911 on a side opposite from the second structure 913.

In this structure, holes in the body region should be released through the body contact 940, so the holes need to escape by moving in one direction. Thus, there may be constraints on the smooth release of holes. In addition, for the holes in the body region below the end of the second structure 913 distal from the first structure 911, as the distance from the body contact 940 increases, the release path also becomes relatively long, and thus there may be additional constraints on the smooth release of the holes. As a result, the breakdown voltage characteristics of the device 9 deteriorate, which may be problematic.

In order to solve these problems, referring to FIGS. 2 to 4, in the RF switch device 1 according to embodiment(s) of the present disclosure, by including a body region 140 along the first direction from approximately the center of the device 1 and in contact with the body contacts 160, the path along which holes move in the body region 140 may decrease so that the holes may escape or release relatively smoothly through the body contacts 160.

For example, the path along which holes move in the body region 140 below opposite ends of the second electrode 113 in the second direction may be short relative to the device 9 in FIG. 1. In other words, the path to the body contact 160 through the body region 140 may be shorter than that of the conventional RF switch device 9. In addition, since a pair of body contacts 160 may be on opposite sides of the device 1 along the first direction, release of holes in more than one direction is also possible.

Furthermore, the device isolation film 150 may surround the active region of the device 1. That is, a first isolation film 151 of the device isolation film 150 may be in the semiconductor layer 103 and may surround the source 120, the drain 130, and the body contacts 160. In addition, one or more second isolation films 153 of the device isolation film 150 may be between the body contact 160 and the source 120 and/or drain 130 adjacent to the body contact 160. The second isolation film 153 may extend along the second direction between the body contact 160 and the adjacent source 120 and/or drain 130, but is not under the first electrode 111. That is, the body region 140 extends uninterruptedly in the semiconductor layer 103 below the first electrode 111 to contact the body contact 160, so the second isolation film 153 is not between the body contact 160 and the adjacent source 120 and/or drain 130 below the first electrode 111.

The body contact 160 is in the semiconductor layer 103 and at least at one end of the first electrode 111, and may be or comprise, for example, a high concentration impurity doped region having the first conductivity type. As previously mentioned, the body contact 160 may comprise a pair of body contacts 160 spaced apart from each other along the first direction. The pair of body contacts 160 may improve breakdown voltage characteristics by allowing the holes in the body region 140 to be released in multiple directions through the body contacts 160 on opposite sides of the device 1. However, it should be noted that the body contact 160 may be only at one end of the first electrode 111 depending on the case, and that the scope of the present disclosure is not limited by specific examples.

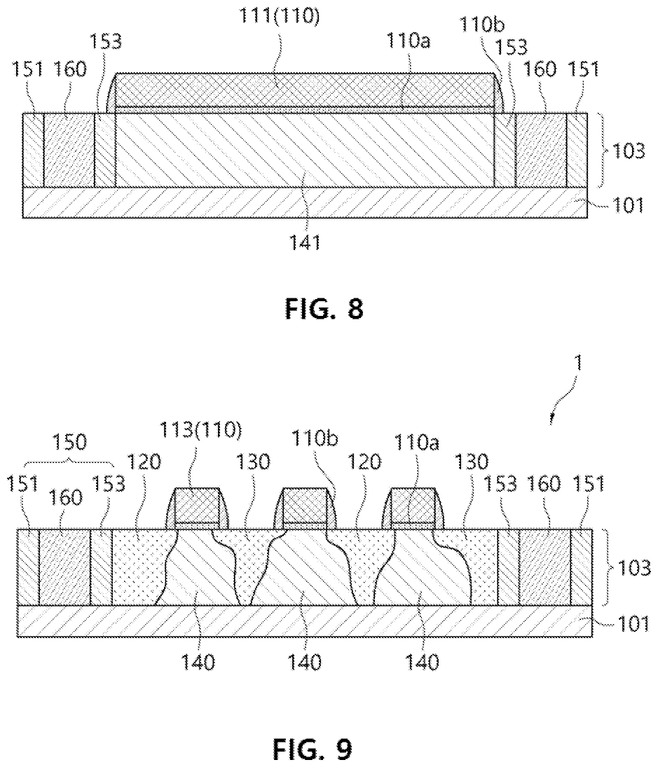

FIGS. 5 to 9 are views showing structures formed in an exemplary manufacturing method of an RF switch device according to one or more embodiments of the present disclosure.

Hereinafter, a method of manufacturing an RF switch device according to embodiment(s) of the present disclosure will be described in detail with reference to the attached drawings. It should be noted that each step in the manufacturing method of an RF switch device according to embodiment(s) of the present disclosure may proceed in a different order or sequence than as described below.

First, referring to FIG. 5, body contacts 160 are formed in the semiconductor layer 103, in turn on the BOX layer 101. The body contacts 160 are doped with a high concentration of impurities having the first conductivity type, and may be formed by ion implantation (e.g., through a mask exposing the areas of the semiconductor layer 103 in which the body contacts 160 are formed). In addition, the body contacts 160 may extend along a second direction on one side of the device 1, or may be spaced apart from each other along the first direction and extend along the second direction on opposite sides of the device, and there is no particular limitation thereto.

Thereafter, referring to FIG. 6, the device isolation film 150 is formed in the semiconductor layer 103. The device isolation film 150 may be formed by etching the semiconductor layer 103 to form a trench and depositing an insulating film in the trench. As previously described, the device isolation film 150 may include a first isolation film 151 in the semiconductor layer 103 surrounding the source 120, the drain 130, and the body contacts 160, and a second isolation film 153 between the body contacts 160 and the adjacent source(s) 120 and/or drain(s) 130.

Thereafter, referring to FIG. 7, an impurity doped region 141 may be formed in the semiconductor layer 103 in the active region of the device 1. The impurity doped region 141 comprises, for example, an impurity doped region having the first conductivity type and may be formed by ion implantation (e.g., through a mask exposing the areas of the semiconductor layer 103 in which the impurity doped region 141 are formed). The impurity doped region 141 is configured to result in formation of the body region 140 after the source(s) 120 and the drain(s) 130 are formed.

Thereafter, referring to FIG. 8, the gate electrode 110 may be formed on the semiconductor layer 103 and/or the impurity doped region 141. To be specific, for example, after depositing and/or growing an insulating film layer on the semiconductor layer 103 and depositing a polysilicon film on the insulating film layer, the gate insulating film 110a and the gate electrode 110 may be formed by etching the polysilicon film and the insulating film layer using a mask pattern exposing the areas of the polysilicon film and the insulating film layer to be removed. The gate electrode 110 may include the first gate electrode portion or structure 111 extending along the first direction and one or more second gate electrode portions or structures 113 extending along the second direction. The first gate electrode portion or structure 111 is preferably at an arbitrary position between opposite ends of the second electrode portion(s) or structure(s) 113, and it is more preferable that the first gate electrode portion or structure 111 extends along the first direction at approximately the center between the opposite ends of the second gate electrode portion(s) or structure(s) 113. In some cases, a plurality of first gate electrode portions or structures 111 may be between opposite ends of the second gate electrode portion(s) or structure(s) 113 in the second direction, spaced apart from each other along the second direction. In this structure, the hole release path may be further decreased.

After the gate electrode 110 is formed, the gate spacer 110b may be formed. The gate spacer 110b may be formed by depositing one or more insulating film layers on the gate electrode 110 and the semiconductor layer 103, and then anisotropically etching the one or more insulating film layers. In addition, a separate mask pattern may not be required during the etching process to form the gate spacer 110b. FIG. 8 shows a cross-sectional view of the first gate electrode portion or structure 111.

Thereafter, referring to FIG. 9, the source(s) 120 and the drain(s) 130 may be formed in the semiconductor layer 103. The source(s) 120 and the drain(s) 130 comprise doped regions with a high concentration of second conductivity type impurities, and may be formed by ion implantation (e.g., through a mask exposing the areas of the semiconductor layer 103 in which the source[s] 120 and the drain[s] 130 are formed). The source(s) 120 and the drain(s) 130 are formed in the impurity doped region 141, thereby completing the body region 140.

The above detailed description is illustrative of the present disclosure. In addition, the above description shows and describes various embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiments describe various implementations of the technical idea(s) of the present disclosure, and various changes for specific applications and/or fields of use of the present disclosure are possible. Accordingly, the detailed description of the present disclosure is not intended to limit the present disclosure to the disclosed embodiments.

What is claimed is:

1. An RF switch device, comprising:
a buried oxide (BOX) layer;
a semiconductor layer on or over the BOX layer; and
a gate electrode on or over the semiconductor layer,
wherein the gate electrode comprises:
a first electrode extending along a first direction; and
at least one second electrode extending along a second direction,
wherein the first electrode is between opposite ends of the second electrode.

2. The RF switch device of claim 1, wherein the first electrode is substantially in a center of the second electrode.

3. The RF switch device of claim 1, further comprising:
a source and a drain adjacent to the second electrode in the semiconductor layer; and
a body region in the semiconductor layer, extending along or under the gate electrode.

4. The RF switch device of claim 3, wherein the body region extends uninterruptedly along the first direction below the first electrode.

5. The RF switch device of claim 3, further comprising:
a device isolation film in the semiconductor layer, surrounding the source and the drain.

6. The RF switch device of claim 5, further comprising:
a body contact in the semiconductor layer, at an end of the first electrode.

7. The RF switch device of claim 6, wherein the body contact is an impurity doped region of a first conductivity type, and has a higher concentration of impurities and/or dopant compared to the body region of a first conductivity type.

8. The RF switch device of claim 6, wherein the device isolation film comprises:
a first isolation film in the semiconductor layer, surrounding the source, the drain, and the body contact; and
a second isolation film extending along the second direction between the body contact and the source and drain adjacent to the body contact.

9. The RF switch device of claim 8, wherein the second isolation film terminates under an end of the first electrode, and the body region extends uninterruptedly in the semiconductor layer below the first electrode.

10. The RF switch device of claim 9, wherein the body region has an end connected to or in contact with the body contact.

11. An RF switch device, comprising:
a buried oxide (BOX) insulating layer;
a semiconductor layer on or over the BOX layer;
a gate electrode on or over the semiconductor layer;
a body region comprising a first conductivity type impurity doped region below the gate electrode; and
a pair of first conductivity type body contacts spaced apart along a first direction,
wherein the gate electrode comprises:
a first electrode extending along the first direction; and
at least one second electrode extending along a second direction,
wherein the first electrode crosses or intersects the at least one second electrode and has opposite ends in the first direction that extend to the pair of body contacts or that overlap or are adjacent to the body contacts.

12. The RF switch device of claim 11, wherein the body region has opposite ends connected to or in contact with the pair of body contacts.

13. The RF switch device of claim 11, further comprising:
a source and a drain in the semiconductor layer, respectively located on opposite sides of the body region on a side of the second electrode.

14. The RF switch device of claim 12, wherein the body region extends along the first direction below the first electrode, and extends along the second direction below the second electrode.

15. The RF switch device of claim 14, wherein the body region extends along the first direction from approximately a center of the device along the second direction and is connected to or in contact with the pair of body contacts.

16. A method of manufacturing an RF switch device, comprising:
forming a body contact extending along a second direction in a semiconductor layer on a buried oxide (BOX) layer;
forming a device isolation film in the semiconductor layer;
forming an impurity doped region in the semiconductor layer;
forming a gate electrode on the semiconductor layer; and
completing a body region by forming a source and a drain in the semiconductor layer,
wherein the gate electrode comprises:
a first electrode extending along a first direction; and
at least one second electrode extending along the second direction, and
the first electrode is between opposite ends of the second electrode.

17. The manufacturing method of claim 16, wherein the body region extends along substantially a same path as the gate electrode.

18. The manufacturing method of claim 17, wherein the body region is connected to or in contact with the body contact.

19. The manufacturing method of claim 18, wherein the body contact comprises a pair spaced apart along the first direction.

20. The manufacturing method of claim 18, wherein the device isolation film extends along the second direction from the body contact or a location adjacent thereto, but terminates below the first electrode.
